(19) United States
(12) Patent Application Publication
(10) Pub. No.: US 2011/0311726 A1
(43) Pub. Date: Dec. 22, 2011

(54) METHOD AND APPARATUS FOR PRECURSOR DELIVERY

(75) Inventors: Guo Liu, Woburn, MA (US); Adam Bertuch, Boston, MA (US); Eric W. Deguns, Somerville, MA (US); Mark J. Dalberth, Somerville, MA (US); Ganesh M. Sundaram, Concord, MA (US); Jill Svenja Becker, Cambridge, MA (US)

(73) Assignee: Cambridge NanoTech Inc., Cambridge, MA (US)

(21) Appl. No.: 13/162,850

(22) Filed: Jun. 17, 2011

Related U.S. Application Data
(60) Provisional application No. 61/397,978, filed on Jun. 18, 2010.

(51) Int. Cl. C23C 16/448; B05C 11/00

(52) U.S. Cl. 427/255.26; 118/695; 118/708; 118/715; 427/255.23

(57) ABSTRACT

An improved precursor vaporization device and method for vaporizing liquid and solid precursors having a low vapor pressure at a desired precursor temperature includes elements and operating methods for injecting an inert gas boost pulse into a precursor container prior to releasing a precursor pulse to a reaction chamber. An improved ALD system and method for growing thin films having more thickness and thickness uniformity at lower precursor temperatures includes devices and operating methods for injecting an inert gas boost pulse into a precursor container prior to releasing a precursor pulse to a reaction chamber and for releasing a plurality of first precursor pulses into a reaction chamber to react with substrates before releasing a different second precursor pulse into the reaction chamber to react with the substrates.

CROSS REFERENCE TO PRIOR APPLICATIONS

This application claims priority under 35 U.S.C. 119(e) based upon Provisional Application Ser. No. 61/397,978, entitled METHOD AND APPARATUS FOR PRECURSOR DELIVERY, filed Jun. 18, 2010 which is incorporated herein by reference in its entirety.

### BACKGROUND OF THE INVENTION

1. Field of the Invention

The present invention relates generally to methods and apparatus for vaporizing liquid and solid precursors for gas deposition and especially for Atomic Layer Deposition (ALD).

2. Description of the Related Art

Gas deposition systems using liquid and solid reactants or precursors include vapor delivery systems configured to vaporize the liquid or solid precursors. In cases where the reactant is a solid material, the solid material may comprise a powder or granular volume of solid material housed in a container, or the solid material may be dissolved or suspended in a liquid housed in the container. Once vaporized, precursor vapor collects in a vapor space of the container and is delivered into a reaction chamber to react with exposed surfaces of solid substrates supported within the reaction chamber. Reactions between the solid substrates and two or more precursors deposit a thin film material layer onto exposed surfaces of the substrates.

Atomic layer deposition (ALD) is one class of gas deposition process. ALD uses a series of self-limiting reactions between precursors and the exposed surfaces. Preferably, the delivery of gaseous or vapor ALD precursors to a reaction chamber is pulse-wise, with each precursor pulse comprising a desired volume of gaseous and or vapor state precursor. Typically, alternating first and second precursor pulses are delivered to the reaction chamber separated by periods of purging the precursor from the reaction chambers. Typically, inert gas is delivered into the reaction chamber during the purging period to flush unreacted precursor out of the reaction chamber and to prevent mixing of dissimilar precursors.

It is desirable to achieve a saturated growth rate in a given ALD process. More specifically, a saturated growth rate occurs when every substrate surface bonding site becomes occupied by a single precursor molecule. The failure to achieve saturated growth rates results in poor thin film coverage (holes) and corresponding variations in the physical and chemical properties of the thin film layer. While a number of parameters contribute to achieving a saturated growth rate; consistent delivery of suitable precursor pulses to the reaction chamber is addressed by the present invention. In particular the achievement of a saturated growth rate depends in part on providing precursor pulses having a sufficient gas volume and precursor vapor pressure to substantially fill the reaction chamber and react with all of the available substrate bonding sites during an allotted exposure time, (i.e. the time that the precursor remains proximate to the substrates). If the precursor vapor pressure is too low, a saturated growth rate may not occur, leaving holes in the thin-film coating. If the precursor vapor pressure is too high, precursor is wasted and any traps used to remove un-reacted precursor from the reaction chamber out flow will have a reduced life cycle due to overdosing precursor input. Typically, liquid and solid precursors are vaporized using a heated gas bubbler or the like to extract vapor from solid or liquid precursor material. While heated gas bubblers are used in many ALD applications, some low vapor pressure precursors, especially solids, are difficult to vaporize fast enough to provide a saturated growth rate in ALD systems using a heated gas bubbler. Instead more complex heated vaporization chambers have been used to increase vaporization rate or the use of some very low vapor pressure precursors has not even been considered plausible as ALD precursors.

Liquid or solid precursors have a vaporization temperature at or above which the entire volume of liquid or solid precursor becomes substantially vaporized. Below the vaporization temperature precursors may be heated to initiate partial vaporization and increase precursor vapor pressure. In practice, precursors tend to breakdown or thermally decompose at or above a thermal breakdown temperature. The thermal breakdown temperature is less than and sometimes significantly less than the precursor vaporization temperature. Thermal break down renders the precursors less viable for the intended reactions with solid substrates such that even if a precursor pulse has sufficient vapor pressure and volume broken down precursor molecules may not participate in the reaction resulting in holes. While heating increases precursor vapor pressure it is desirable to avoid exceeding the precursor thermal breakdown temperature and precursor thermal breakdown. Unfortunately, many low vapor pressure precursors, e.g. solids and especially metals, do not generate sufficient vapor pressure for reliable ALD reactions without heating the precursors above their thermal break down temperature.

A heated gas bubbler is constructed to heat the precursor and pass an inert gas flow through a liquid or solid precursor housed in a container. The inert gas flow increases vaporization, collects and mixes with precursor vapor and increase precursor vapor pressure. Heating the precursor or the container further increases vaporization and precursor vapor pressure. FIG. 1 depicts a schematic view of a gas bubbler (100). The gas bubbler (100) comprises a precursor container (105) partially filled with a liquid or solid precursor to a precursor level (110). The precursor level (110) varies as precursor is added to fill the container or is removed by vaporization. A vapor space (120) is provided above the precursor level (110) to collect precursor vapor. An inert gas supply delivers inert gas into the container (105) through an inlet conduit (135). The inlet conduit extends into the container (105) and below the precursor level (110) such that inert gas entering the container bubbles or flows upward through the precursor to the vapor space (120). The inert gas collects and mixes with precursor vapor as it passes through the liquid or solid precursor and a mixture of inert gas and precursor vapor collects in the vapor space.

A controllable input valve (140) may be disposed between the inert gas supply and the container (105) to modulate the flow of inert gas into the container (105). An outlet conduit (125) extends between the vapor space (120) and a reaction chamber. A controllable outlet valve (130) may be disposed between the vapor space (120) and the reaction chamber to modulate the flow of precursor vapor between the vapor space and the reaction chamber. Each conduit (125, 135) may include a manual valve (145) which is opened during automated operation and closed during non-operating periods. The bubbler container (105) and or the outlet conduit (125) are usually heated to increase precursor vapor pressure.

In another example, a heated gas bubbler is disclosed in U.S. Pat. No. 6,337,102 to Forrest et al. entitled LOW PRESSURE VAPOR PHASE DEPOSITION OF ORGANIC FILMS. Forrest et al. disclose an inlet conduit extending between an inert gas supply and a gas bubbler and the inlet conduit includes a gas pressure regulator, flow meter and a quick switching valve in series. Forrest et al. further disclose an outlet conduit extending between the gas bubbler and a reaction chamber and the outlet conduit is free of valves or other gas flow restrictors. One problem with the gas bubbler disclosed by Forrest et al. is that inert gas entering the gas bubbler passes through to the reaction chamber without increasing total gas pressure or precursor vapor pressure in the vapor space.

In another example, a heated gas bubbler is disclosed in U.S. Pat. No. 6,117,772 to Murzin entitled METHOD AND APPARATUS FOR BLANKET ALUMINUM CVD ON SPHERICAL INTEGRATED CIRCUITS. Murzin discloses an inlet conduit extending between an inert gas supply and a gas bubbler and the inlet conduit includes a regulator, a mass flow controller and a pneumatic inlet valve. Murzin further disclose an outlet conduit extending between the gas bubbler and a reaction chamber and the outlet conduit includes a pneumatic outlet valve. One problem with the gas bubbler disclosed by Murzin is that the system is difficult to control especially at low gas volumes and vapor pressures.

Generally conventional gas bubblers are difficult to control, especially at low gas volumes and vapor pressures. Additionally, the performance of a heated gas bubbler varies with changes in the precursor level (110). In particular, the precursor vapor delivery rate to a reaction chamber tends to decrease with decreasing precursor level (110). Both problems lead to fluctuations in precursor vapor pressure and delivery rates to the reaction chamber, which in turn either overdose or underdose the desired saturated growth rate. To avoid underdosing, conventional heated gas bubblers are operated with a higher than necessary flow of inert gas input which tends to massively overdose precursor vapor input to the reaction chamber. The massive overdose leads to excessive consumption of precursor and if a trap is used to remove unused precursor from outflow from the reaction chamber, the trap life is unnecessarily shortened by the massive overdose of precursor vapor input.

Another problem with conventional heated gas bubblers is that the container (105) includes two ports and the input conduit (135) extends into the container nearly to the bottom and this increase part cost and system complexity. In contrast a conventional gas precursor container includes only one port. As a result, a gas precursor container and a gas bubbler used for liquid and solid precursors are not interchangeable within the same system. This further increases part cost and system complexity.

While a heated bubbler provides acceptable results for many precursors, especially liquids, the heated bubbler is more effective and its systems simplified when the bubbler is operated with a constant gas throughput, which is not useful in ALD systems. Additionally a heated gas bubbler does not provide acceptable results for low vapor pressure precursors such as metal halides, metal alkyls, metal alkoxides, metal amides, metallocenes, diketonates and amidinates/guanides, which have a vapor pressure ranging from 0.05-10.0 Torr in the desired precursor temperature range of 70-130° C.

The problem of vaporizing low vapor pressure precursors and delivering the precursors pulse-wise is addressed in U.S. Pat. Appl. 2004/0079286 to Lindfors entitled METHOD AND APPARATUS FOR THE PULSE-WISE SUPPLY OF A VAPORIZED LIQUID REACTANT. Lindfors discloses a vaporization system comprising an external precursor container maintained at temperature T1, (e.g. ambient), a precursor vaporization chamber heated to a source or precursor temperature T2 and an internal reaction chamber heated to a reaction temperature T3. According to Lindfors, temperature T2 is sufficiently high to facilitate the production and transport to the reaction chamber of an adequate amount of vaporized reactant; and T2 is less than or equal to T3. Liquid precursor is delivered from the external precursor container to the precursor vaporization chamber and heated to the source temperature T2 to initiate vaporization. An inert gas supply is connected to the vaporization chamber by an inlet conduit that includes a flow control device and a pulsing valve and inert gas is supplied pulse wise to the vaporization chamber. Pulses of precursor vapor are delivered from the vaporization chamber to the reaction chamber by pulsing the inert gas pulsing valve. One problem with the disclosure by Lindfors is that the source temperature T2 is likely above the precursor thermal breakdown temperature (e.g. 200° C.). However Lindfors suggests that precursor thermal breakdown only occurs after prolonged exposure to high temperatures. Another problem with the disclosure by Lindfors is that the system is complicated, costly and difficult to operate. A further problem is that the vaporization chamber is not sealed during ALD cycles and this prevents increases in gas pressure within the vaporization chamber.

### BRIEF SUMMARY OF THE INVENTION

In view of the shortcomings of the prior art described above, it is an object of the present invention to enable the use of low vapor pressure liquid and solid precursors (e.g. having a vapor pressure of 0.05-10.0 Torr below the precursor thermal breakdown temperatures) without heating the precursor above a thermal breakdown temperature, (e.g. >139° C.) for tetrakis(dimethylamido)hafnium, Hf(NMe₂)₄. Specific precursor examples include Er(iPrCp)₃ and O₃ for production of Er₂O₃; use of (EtCp)₂Ni or (iPrCp)₂Ni or NiCp₂ and O₃ for the production of NiO. However the present invention provides advantages when used with other low vapor pressure precursor materials including metal halides, metal alkyls, metal alkoxides, metal amides, metallocenes, diketonates and amidinates/guanides. It is a further object of the present invention to generate precursor vapor pulses suitable for achieving ALD reactions at saturated growth rates.

The invention includes a gas deposition system having a first precursor container partially filled with a non-vaporized precursor. Specifically, a non-vaporized precursor comprises any liquid or solid material that can be converted to a gaseous or vapor state. Moreover, the non-vaporized precursors referred to in the present example have a vapor state that provides a desireable gas deposition precursor. A vapor space is formed in the precursor container above the non-vaporized precursor for collecting precursor vapor as the non-vaporized material is converted to its vapor state. An inlet conduit extends between an inert gas supply and the vapor space and an outlet conduit extends between the vapor space and a reaction chamber. The reaction chamber houses one or more solid substrates for reacting with vaporized precursors in order to form thin film material layers onto exposed surfaces of the substrates.

A first pulse valve is disposed along the outlet conduit between the vapor space and a reaction chamber and a second pulse valve is disposed along the inlet conduit between the inert gas supply and the vapor space. A gas flow restrictor is disposed along the inlet conduit between the inert gas supply and the second pulse valve. An electronic controller is in communication with each of the first and second pulse valves and is configured to independently pulse each of the first and second pulse valves at any desired pulse duration or pulse frequency within a range of pulse duration and frequency capabilities of the pulse valves. In some embodiments the first precursor container includes an outer wall with a single port passing though the outer wall to the vapor space and each of the inlet and outlet conduits is in fluid communication with the vapor space through the single port. A gas pressure sensor in communication with the electronic controller may be positioned to monitor gas pressure in the vapor space. A heater disposed to heat the non-vaporized precursor inside the first precursor container and a temperature sensor in communication with the electronic controller may be positioned to monitor the temperature of the non-vaporized precursor and adjust power input to the heater to maintain a desired precursor temperature. In one embodiment, wherein inert gas inlet pressure is less than 40 psi, the gas flow restrictor may comprise an orifice with a circular diameter of 100-150 microns. In another embodiment, wherein the inert gas inlet pressure is more than 40 psi, the gas flow restrictor may comprise a third pulse valve disposed along the inlet conduit between the inert gas supply and the second pulse valve. In this case, an inert gas storage volume is disposed between the second and third pulse valves such that pulsing the third pulse valve fills the inert gas storage volume and pulsing the second pulse valve with the third pulse valve closed injects an inert gas pulse into the vapor space. A gas pressure sensor in communication with the controller and positioned to monitor gas pressure in the inert gas storage volume may be included. Accordingly, gas pressure within the inert gas storage volume may be monitored and adjusted form one pulse to another by changing the pulse duration or the third pulse valve to achieve a desired gas pressure in the inert gas storage volume. The inert gas storage volume may comprise a variable volume.

The invention includes a gas deposition method comprising partially filling a first precursor container with a non-vaporized precursor and providing a vapor space in the first precursor container. A first pulse valve disposed along an outlet conduit between the vapor space and a reaction chamber is initially closed to seal the vapor space. An inert gas pulse is injected into the sealed vapor space with the first pulse valve closed by opening a second pulse valve. The second pulse valve is disposed along an inlet conduit between the inert gas supply and the vapor space. The inert gas pulse increases total gas pressure in the container, increases vapor pressure in the container, and mixes inert gas and precursor vapor in the vapor space. After injecting an inert gas pulse into the container, the second pulse valve is closed and the first pulse valve is pulsed to release a precursor pulse from the vapor space to the reaction chamber. The method further includes restricting gas flow between the inert gas supply and the second pulse valve. Gas flow restriction may be provided by an orifice disposed between the inert gas supply and the second pulse valve or by providing a third pulse valve disposed between the inert gas supply and the second pulse valve and an inert gas storage volume disposed between the second and third pulse valves. The method further includes heating the non-vaporized precursor to a temperature that is below its thermal breakdown temperature.

Further methods according to the invention include: partially filling a first precursor container with a first non-vaporized precursor and providing a vapor space in the first precursor container; closing a first pulse valve disposed along an outlet conduit between the vapor space and a reaction chamber while injecting an inert gas pulse into the vapor space; closing a second pulse valve disposed along the inlet conduit between the inert gas supply and the vapor space while releasing a precursor pulse comprising the first precursor from the vapor space to the reaction chamber; reacting the first precursor with a substrate disposed inside the reaction chamber and then repeating the steps of injecting an inert gas pulse into the vapor space and releasing a precursor pulse from the vapor space to the reaction chamber and reacting the first precursor with the substrate before purging the reaction chamber of the first precursor and reacting a second precursor with the substrate and purging the second precursor from the reaction chamber.

### BRIEF DESCRIPTION OF THE DRAWINGS

The features of the present invention will best be understood from a detailed description of the invention and a preferred embodiment thereof selected for the purposes of illustration and shown in the accompanying drawings in which:

FIG. 1 depicts a schematic view of a conventional gas bubbler according to one example of the prior art.

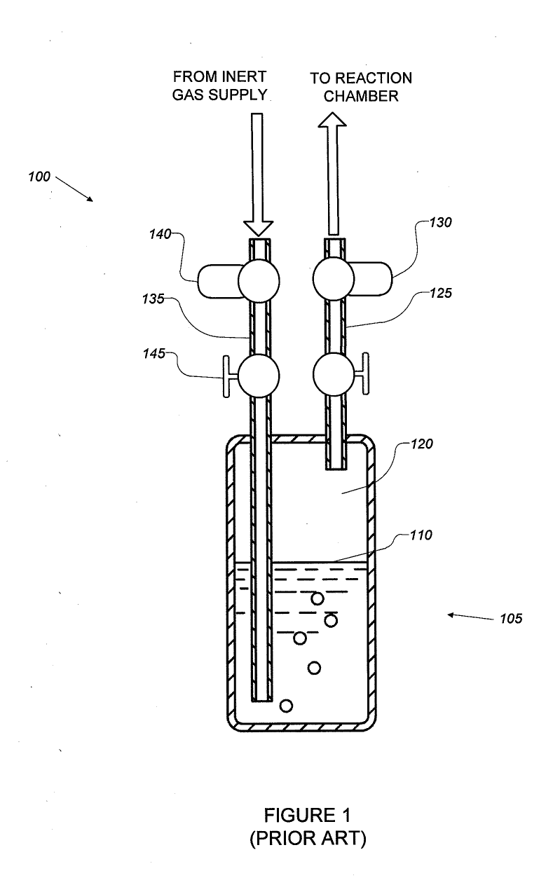

FIG. 2 depicts a first example vapor draw system according to the present invention.

FIG. 2a depicts a second example vapor draw system according to the present invention.

FIG. 3 illustrates an orifice fitting usable as a vapor draw system gas flow restrictor according to a preferred embodiment of the present invention.

FIG. 4 depicts an ALD system that includes a vapor draw system according to the present invention.

FIG. 5 depicts a plot of HfO₂ growth rate vs. precursor temperature for Hf(NEtMe)₄ at various positions of a circular wafer based on experimental results using process steps according to the present invention.

FIG. 6 depicts a plot of precursor vapor pressure vs. precursor temperature for TEMAHf using Hausmann experimental data vs. SAFC data.

FIG. 7 depicts a plot of precursor container peak pressure vs. inert gas inlet pressure for various boost pulse durations according to experiment results using process steps of the present invention.

ITEM NUMBER LIST

| Item Number | Description |
|---|---|
| 100 | Gas Bubbler |
| 105 | Sealed precursor container |
| 110 | Precursor level |
| 115 | N/A |
| 120 | Vapor space |
| 125 | Exit conduit |
| 130 | Outlet valve |
| 135 | Input conduit |
| 140 | Inlet valve |
| 145 | Manual valve |
| 150 | N/A |
| 200 | Vapor draw system |
| 200a | Second configuration vapor draw system |
| 205 | N/A |
| 210 | Precursor container |
| 210a | Second configuration precursor container |
| 215 | Liquid or solid precursor |
| 220 | Vapor space |
| 225 | Input conduit |
| 230 | Output conduit |
| 235 | Manual valve |
| 240 | Heating elements |
| 245 | Electronic controller |
| 250 | ALD pulse valve |
| 255 | Temperature sensor |
| 260 | Boost pulse valve |
| 265 | Flow restrictor |
| | (third pulse valve in some embodiments) |
| 270 | Inert gas pulse (aka boost pulse) |
| 275 | Precursor vapor pulse |
| 280 | Inert gas storage volume |
| 285 | Pressure sensor |
| 290 | Pressure sensor |
| 295 | N/A |
| 300 | Orifice assembly |
| 310 | Orifice washer |
| 315 | Orifice |
| 320 | Female fitting |
| 325 | Male fitting |
| 400 | ALD system |
| 405 | Reaction chamber |
| 408 | Substrate |
| 410 | 1^{st} Precursor container |
| 412 | Liquid or solid precursor |
| 415 | 2^{nd} Precursor container |
| 420 | Manifold |
| 425 | Output conduit |
| 426 | Manual valve |
| 430 | Output conduit |
| 435 | Manifold conduit |
| 440 | Vacuum pump |
| 442 | Exit port |
| 444 | Input port |
| 445 | Trap |
| 450 | Stop Valve |
| 455 | Chamber pressure sensor |
| 460 | First ALD pulse valve |
| 465 | Second ALD pulse valve |
| 470 | Inert gas supply |
| 475 | Inert gas supply |
| 480 | Electronic controller |
| 485 | N/A |
| 490 | Inert gas supply |
| 492 | Inert gas input conduit |
| 495 | Gas flow restrictor |
| 498 | ALD boost valve |
| 500 | Film growth vs. precursor temperature |
| 510 | Data curve no boost pulse |
| 520 | Data curve 1 boost pulse |
| 530 | Data curve 2 boost pulses |
| 540 | Data curve 3 boost pulses |
| 600 | Vapor pressure vs. precursor temperature |
| 610 | SAFC Data |
| 620 | Hausmann experimental data |

### DESCRIPTION OF THE PREFERRED EMBODIMENTS

The present invention comprises a vapor draw system (200) for improved vaporization of liquid or solid precursors and especially liquid or solid precursors that have a low vapor pressure at temperatures below 250° C. The vapor draw system (200) replaces conventional precursor bubblers and allows the gas deposition system designer to use conventional gas precursor containers for gas, liquid, and sold precursors, including low vapor liquid and solid precursors. The vapor draw system of the present invention provides increased precursor vapor pressure at reduced precursor temperatures. More importantly, the vapor draw system of the present invention enables the use of some low vapor pressure precursors without heating the precursors above a precursor thermal breakdown temperature.

The vapor draw system (200) of the present invention interfaces with a conventional gas precursor container (210) which is partially filled with a liquid or solid precursor and injects a single pulse of inert gas (270), also called a boost pulse, into the partially filled precursor container prior to delivering each precursor pulse (275) from the precursor container into a reaction chamber. The partially filled precursor container comprises a substantially sealed container and provides a vapor space (220) above the level of liquid or solid precursor contained therein. Each inert gas pulse (270) injected into the partially filled precursor container comprises a precisely controlled volume of inert gas which when injected into the precursor container increases the overall gas pressure within the partially filled precursor container and also increases the partial pressure of precursor vapor contained within the vapor space (220). The vapor draw system of the present invention includes heating elements (240) associated with the precursor container for heating the liquid or solid precursor contained therein and combines heating the precursor to a temperature that is below a thermal breakdown temperature of the precursor with injecting an inert gas pulse into the precursor container. The description provided below includes several embodiments of vapor draw systems, ALD gas deposition systems, and methods for operating the vapor draw systems and ALD gas deposition systems.

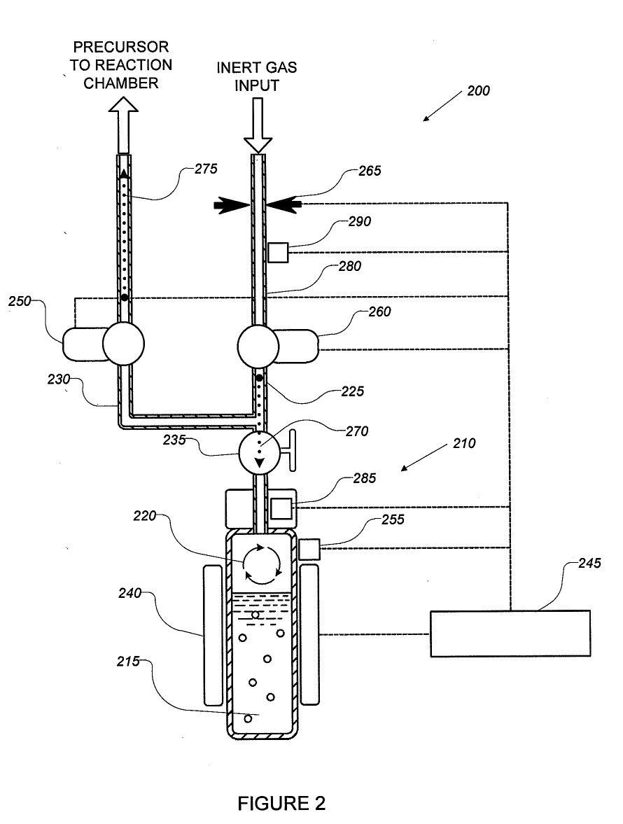

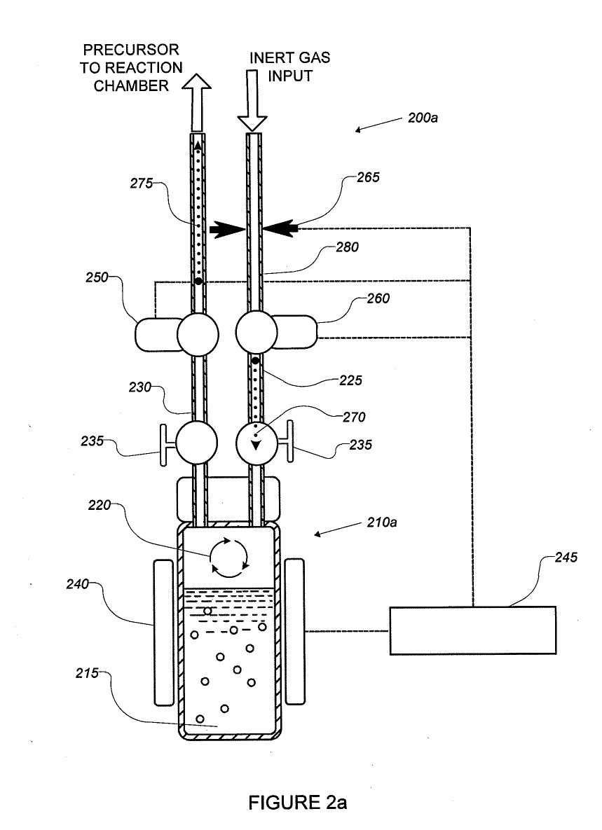

Referring now to FIG. 2 a first example vapor draw system (200) according to the present invention is shown schematically. The vapor draw system (200) includes a conventional gas precursor container (210). The container (210) comprises a single port interfaced with an input conduit (225). The container (210) is partially filled with a liquid or solid precursor (215) and a vapor space (220) is provided above the level of liquid or solid precursor (215). The input conduit (225) which extends between and fluidly connects the vapor space (220) with an inert gas supply. An output conduit (230) interfaces with the input conduit (225) at an elbow, or the like, such that the output conduit extends between and fluidly connects the vapor space (220) with a reaction chamber. A manual valve (235) is optionally provided along the input conduit (225) for isolating the precursor container (210) from the inert gas supply and for isolating the output conduit (230) from the reaction chamber when the manual valve (235) is closed. The manual valve may be closed when the container (210) is not in use or may be closed to remove the container (210) for refill or replacement.

Heating elements (240) are provided for heating precursor contained within the container (210). The heating elements are driven by an electronic controller (245). Optionally, a temperature sensor (255) associated with the precursor container (210) may be provided to monitor precursor temperature and communicate a temperature signal to the controller (245). Optionally, the controller includes elements for monitoring and recording precursor temperature and a temperature feedback loop configured to maintain precursor temperature at a desired substantially constant precursor temperature which may be selected from a range of desired precursor temperatures depending on the precursor and gas deposition process being performed. Preferably, the precursor is maintained at a temperature that is below a thermal breakdown temperature of the precursor vapor contained within the vapor space (220). According to one aspect of the invention, the temperature of the liquid or solid precursor (215) is raised by the heating elements but maintained below a thermal breakdown temperature of the precursor. As the precursor temperature is increased, the liquid or solid precursor (215) begins to vaporize and precursor vapor collects in the vapor space (220). However at temperatures below the precursor vaporization temperature, precursor vaporization is incomplete and a precursor vaporization rate may be inconsistent such that precursor vapor pressure within the vapor space (220) may vary with time.

In one non-limiting example embodiment, the inert gas supply may comprise a pressurized gas cylinder and an associated pressure regulator for reducer or regulating inert gas input pressure to the input conduit (225) to a range of 20-40 psi and a conventional ALD or pulse valve (260) is disposed along the input conduit (225) between the inert gas supply and the vapor space (220). The ALD pulse valve (260) is normally closed, sealing and isolating the precursor container from the inert gas supply; however, the valve (260) is periodically pulsed open to inject a pulse of inert gas (270) into the vapor space (220). The injected inert gas pulse increases overall pressure in the precursor container as well as increasing the precursor vaporization rate, the precursor vapor pressure and gas mixing in the container. After injecting an inert gas pulse into the vapor space (220) a second ALD or pulse valve (250) disposed along the output conduit (230) between the vapor space (220) and the reaction chamber is pulsed to release a precursor pulse (275) into the reaction chamber.

In operation, when both of the first and second ALD pulse valves (250, 260) are closed the vapor space (220) is sealed, allowing precursor vapor pressure to build up therein. Both ALD valves (250, 260) are controlled by the electronic controller (245). The controller and ALD valves are configured to open and close, or pulse, each ALD valve independently. Each ALD valve (250, 260) is pulsed with a pulse duration or pulse period which is the elapsed time between beginning to open the ALD valve and fully closing the ALD valve. The controller (245) is configured to independently vary the pulse duration of each ALD valve as required. In preferred embodiments, the second ALD pulse valve (250) may be configured to operate with pulse durations as short as 5 ms and the first ALD valve (260) may be configured to operate with pulse durations as short as 20 ms, however the first and second ALD valves (260, 250) may be substantially identical. Preferably, the controller (245) and ALD valves (250, 260) are configured to independently vary pulse duration over a range of 5 ms-1 second and to independently vary pulse frequencies over a range of fully open or not pulsing to pulsing at a rate of up to 200 pulses per second.

According to the invention, the vapor draw system (200) includes a gas flow restrictor (265) disposed between the inert gas supply and the second ALD valve (260). The gas flow restrictor (265) is provided to restrict the mass flow rate and or the volume of inert gas flowing through the second ALD valve (260) during pulses of the ALD valve and preferably the gas flow restrictor (265) operates in cooperation with the first ALD valve (260) to generate inert gas pulses (270) that have a substantially uniform gas volume or mass flow from pulse to pulse.

In a preferred embodiment, the gas flow restrictor (265) comprises an orifice, described below. The orifice is disposed in the input conduit (225) between the inert gas supply and the first ALD valve (260). The orifice is sized to limit the volume of inert gas flowing through the input conduit (225) while the first ALD valve (260) is open. In another embodiment of the vapor draw system (200) the flow restrictor (265) comprises a third pulse valve, controlled by the electronic controller (245). The third pulse valve and controller (245) may be configured to operate with substantially the same operating characteristics set forth above in the description of the first and second ALD valves (260, 250) with all three valves being independently controlled to vary pulse duration and pulse frequency. Alternately, a third pulse valve having a fixed pulse duration is usable without deviating from the present invention.

In a preferred vapor draw system (200) the gas restrictor (265) comprises an orifice, described below, and the system (200) operates as follows. In an initial state, the first and second ALD pulse valves (250, 260) are closed and the heating element (240) is operating to maintain the liquid or solid precursor (215) at a desired precursor temperature. Preferably, the desired precursor temperature is substantially equal to a reaction temperature associated with an ALD reaction being carried out in the reaction chamber. The desired ALD reaction temperature provides a favorable reaction between the precursor vapor and exposed surfaces of a substrate housed in the reaction chamber. Additionally, the desired precursor temperature is less than a thermal breakdown temperature of the liquid or solid precursor contained within the precursor container (210).

### Operation of the Orifice Embodiment

The orifice embodiment of vapor draw system (200) operates as follows. With the first and second ALD pulse valves (260, 250) closed, precursor vapor accumulates in the vapor space (220). In a first step the first ALD valve (260) is pulsed releasing an inert gas pulse (270) into the vapor space. The inert gas pulse (270) has a gas pressure that is substantially equal to or less than the gas pressure between the first ALD valve and the orifice and the mass flow rate of inert gas passing through the first ALD valve (260) during the pulse duration is equal to or less than the mass flow rate of inert gas passing through the orifice during the pulse duration. The inert gas pulse (270) increases the gas pressure inside the precursor container (210), agitates the precursor vapor in the vapor space (220), agitates precursor vapor being released from the liquid or solid precursor, and mixes precursor vapor with inert gas.

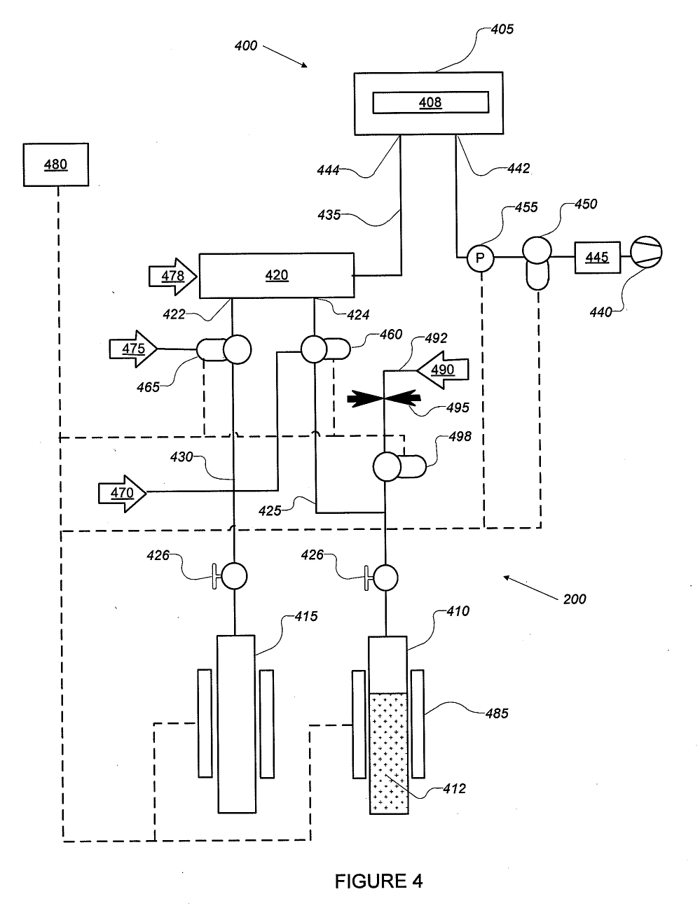

In a second operating step, with the first ALD valve (260) closed, the second ALD valve (250) is pulsed releasing a precursor pulse (275) from the vapor space (220) to the reaction chamber. The precursor pulse (275) reacts with the exposed surface of solid substrates housed within the reaction chamber, shown in FIG. 4. The precursor pulse (275) contributes to depositing a single thin film layer onto exposed surface of substrates housed within the reaction chamber. The sequence of injecting a single inert gas pulse (225) into the vapor space (220) prior to releasing each single precursor pulse (275) into the reaction chamber is repeated for each precursor pulse (275). The entire sequence of injecting a single inert gas pulse (225) into the vapor space (220), and releasing a single precursor pulse (275) to the reaction chamber is repeated for each new thin film layer being formed on the exposed surfaces of substrates housed in the reaction chamber. Alternately, as will be further described below, a plurality of precursor pulses (275) may be injected into the reaction chamber for each new thin film layer being formed, and an inert gas pulse is injected into the vapor space prior to releasing each of the plurality of precursor pulses into the reaction chamber.

### Orifice Assembly

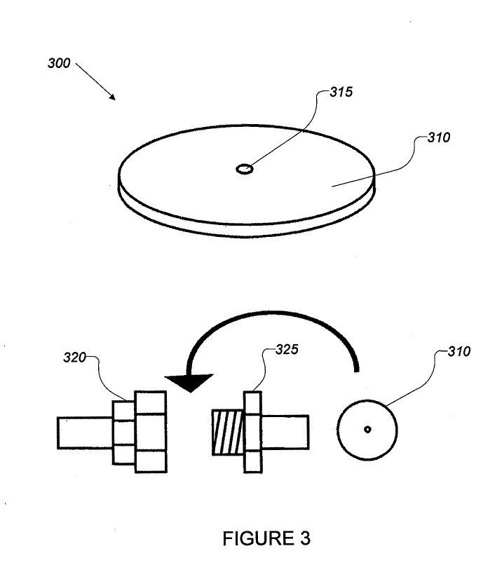

Referring now to FIGS. 2 and 3, in a preferred embodiment of the vapor draw system (200), the gas flow restrictor (265) comprises an orifice assembly (300). The orifice assembly (300) is disposed along the input conduit (225) between the inert gas supply and the first ALD valve (260). The orifice assembly (300) includes a disk shaped orifice washer (310) formed with a center aperture or orifice (315) passing through the orifice washer (310). The orifice (315) is preferably circular with a diameter in the range of 10-1000 microns. However, other orifice shapes such as square, rectangular, oval, and star-shaped or any other shapes are useable without deviating from the present invention. Similarly, the orifice washer (310) may comprise a plurality of orifice washers each having increasingly smaller orifice diameters or areas to produce a multistage flow restrictor. The orifice assembly (300) includes a female connector (320) and a mating male connector (325) each fitted into the input conduit (225) with a gas seal. The disk-shaped orifice washer (310) installs between the fittings (320) and (325) in a gas tight internal cavity formed there between. For a multistage flow restrictor, a plurality of orifice washers (310) may be installed within the internal cavity with the washers spaced apart along a gas flow direction. The orifice assembly (300) may also include one or more O-rings or gaskets installed inside the connectors (320, 325) as required to provide a gas seal. One example orifice washer (310) suitable for use with the present invention comprises a silver-plated stainless steel disk washer drilled by a laser drilling device such as is available from Lenox Laser (part number: SS-4-VCR-2).

In a typical application, the inert gas supply comprises a pressurized gas cylinder and a gas pressure regulator separate from the flow restrictor (265) for reducing and regulating inert gas pressure to a range of 20-40 pounds per square inch (psi) at the input to the orifice or gas flow restrictor (265). For an input pressure of 20-40 psi, a circular orifice (315) having a diameter in the range of 100-150 microns is desirable. In operation, when the first ALD pulse valve (260) is pulsed open, gas from the inert gas supply flows through the orifice assembly (300) passing through the orifice (315). As inert gas passes through the orifice (315), its flow rate and gas pressure are reduced and its flow velocity is increased. Accordingly the orifice (315) restricts the mass flow rate of inert gas that can pass through the first ALD valve (260) even when the valve (260) is fully opened. Moreover, by proper selection of the inert gas input pressure, the area of the orifice (315) and the pulse duration of the first ALD valve (260), each inert gas pulse (270) can be adjusted to have a desired volume of inert gas which is substantially identical from pulse to pulse for a given pulse duration. In one example, using a circular orifice (315) having a diameter of 1 micron and a 40 psi input pressure, a 15 ms inert gas pulse period produces an inert gas pulse (270) having a gas volume of approximately 0.1 ml. Under these same conditions, when the inert gas pulse period is increased to 1 second the inert gas pulse volume increases to approximately 4 ml.

Boost vs. Inert gas Input Pressure and Boost Pulse Duration

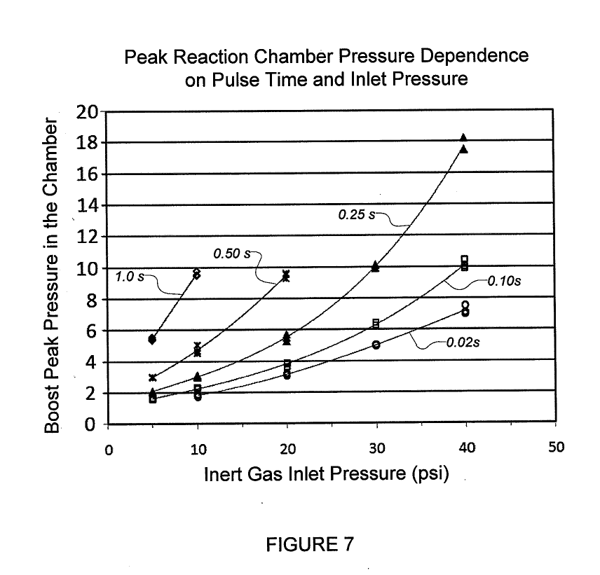

Referring now to FIG. 7, peak or boost gas pressure within the reaction chamber generated by the introduction of a precursor pulse into the chamber is plotted vs. inert gas input pressure to the orifice (315) for various pulse durations of the first ALD valve (260). Generally the reaction chamber is maintained at substantially constant vacuum pressure by a vacuum pump, described below. Each precursor pulse introduced into the reaction chamber briefly spikes gas pressure within the reaction chamber to a peak pressure, which is measurable by a pressure sensor associated with the reaction chamber, described below, and the peak pressure includes partial pressures, comprising precursor vapor pressure and inert gas pressure associated with an inert gas pulse (270).

The data plotted in FIG. 7 was generated by selecting an inert gas input pressure to the orifice (315) and measuring peak or boost pressure in the reaction chamber for a plurality of pulse durations of the ALD valve (260). The inert gas pressure is varied over the range of 5-40 psi and the pulse duration is varied over the range of 20 ms to 1 second. Each curve plotted on FIG. 7 relates to a single pulse duration. For a pulse duration of 1 second, reaction chamber peak pressure increases linearly with increasing inert gas input pressure. For all other pulse durations reaction chamber peak pressure increases non-linearly with increasing inert gas pressure. Referring to the curve associated with a 20 ms pulse duration, gas reaction chamber peak pressure increase with increasing inert gas input pressure is small compared to longer pulse durations and increases from 2 to 7 Torr over an inert gas input pressure range of 5-40 psi. As is further shown by the data of FIG. 7, for a constant inert gas input pressure, e.g. 30 psi, reaction chamber peak pressure can be varied in very fine increments between about 4 and 10 Torr by varying the pulse duration of the first ALD valve (260) between 20-250 ms. Accordingly the vapor draw system (200) provides a means of making small variations in reaction chamber peak pressure and therefore precursor vapor pressure and such small variations are not achievable using a conventional gas bubbler. As will be further discussed below, small variations in reaction chamber peak pressure due to precursor pulses can be used to fine tune an ALD coating cycle to achieve a saturated growth rate without over-dosing the substrate with precursor.

### Third Pulse Valve Embodiment

In an alternate embodiment of the vapor draw system (200) the gas restrictor (265) comprises a third pulse or actuator valve under the control of the controller (245). The third pulse valve may be substantially identical in construction and operation to the first and second ALD valves (250, 260) described above or may comprise another suitable actuator valve. Referring now to FIG. 2 the gas restrictor (265) comprises a third pulse valve disposed in the input conduit (225) between the inert gas supply and the first ALD valve (260). A section of the input conduit extending between the third pulse valve (265) and the first ALD valve (260) serves as an inert gas storage volume (280). In the example shown in FIG. 2, the fixed volume is bounded by the conduit diameter and the length of the conduit that extends between the third pulse valve (265) and the first ALD valve (260). Alternately, inert gas storage volume (280) may comprise other fixed volume gas storage containers in fluid communication with the input conduit (225) between the third pulse valve (265) and the first ALD valve (260). Alternately, the inert gas storage volume (280) may comprise a variable volume gas container such as a flexible balloon or bellows which expands as gas is input. In other embodiments the inert gas storage volume (280) may comprise a variable volume gas container such as a mechanically actuated bellows which is expanded and contracted by an actuator to change the volume of the inert gas storage volume (280). Alternately the inert gas storage volume (280) may comprise a multi-chamber gas storage container having actuator valves disposed between chambers to increase or decrease gas storage volume by actuating valves to open or close access to the chambers. Moreover, any actuator may be interfaced with the controller (245) to be actuated as required to vary the volume of the inert gas storage volume (280).

In the case of a fixed volume inert gas storage volume (280) the storage volume is known. In the case wherein an actuator is used to vary the volume of the inert gas storage volume (280), the container volume can be varied to different known and fixed volumes. The volume of inert gas stored in the inert gas storage volume (280) depends in part on the inert gas input pressure, the gas temperature and the pulse duration of the third pulse valve as the third pulse valve is opened to fill the inert gas storage volume with inert gas. In the case of the a variable volume inert gas storage volume (280) the volume of inert gas stored therein depends in part on a spring force or elasticity of elements of the storage container as well as the inert gas input pressure, the gas temperature and the pulse duration of the third pulse valve as the third pulse valve is opened to fill the inert gas storage volume with inert gas.

### Operation of the Third Pulse Valve Embodiment

The third pulse valve embodiment of vapor draw system (200) operates as follows. With the first and second ALD pulse valves (260, 250) closed, precursor vapor accumulates in the vapor space (220). In a first step the third pulse valve (265) is pulsed releasing inert gas into the gas storage volume (280). In a second step, with the second ALD valve (250) and the third pulse valve (265) closed, the first ALD valve (260) is pulsed releasing an inert gas pulse (270) from the inert gas storage volume (280) to the vapor space (220). The inert gas pulse (270) has a gas pressure and volume of inert gas that is substantially equal to or less than the gas pressure and volume of inert gas stored inside the gas storage volume (280). The inert gas pulse (270) increases the gas pressure inside the precursor container (210), agitates the precursor vapor in the vapor space (220), agitates precursor vapor being released from the liquid or solid precursor and mixes precursor vapor with inert gas.

In a second operating step, the first ALD valve (260) and the third pulse valve (265) are closed, the second ALD valve (250) is pulsed releasing a precursor pulse (275) from the vapor space (220) to the reaction chamber. The precursor pulse (275) reacts with exposed surface of solid substrates housed within the reaction chamber, shown in FIG. 4 and contributes to depositing a single thin film layer onto exposed surface of substrates housed within the reaction chamber. The entire sequence of injecting inert gas into the inert gas storage volume (280), injecting a single inert gas pulse (225) into the vapor space (220), and releasing a single precursor pulse (275) to the reaction chamber is repeated for each new thin film layer being formed on the exposed surfaces of substrates housed in the reaction chamber. Alternately, as will be further described below, a plurality of precursor pulses (275) may be injected into the reaction chamber for each new thin film layer being formed and inert gas is released into the gas storage volume (280) and an inert gas pulse is injected into the vapor space prior to releasing each of the plurality of precursor pulses into the reaction chamber.

As compared to the vapor draw system (200) configured with an orifice (315), the alternate vapor draw system (200) configured with a third pulse valve (265) and a fixed volume inert gas storage volume (280) is more suitable for use when the inert gas supply input pressure is between 40-300 psi or when the inert gas supply pressure varies widely in input pressure. In particular, when the inert gas storage volume (280) is a fixed volume, the volume of inert gas injected therein during each pulse of the third pulse valve (265) of the same pulse duration remains substantially constant from pulse to pulse, even over a wide inert gas input pressure range such as 100 Torr-300 psi, as long as the inert gas supply pressure exceeds the vapor pressure and subsequently the process chamber presure. Additionally the third pulse valve (265) may be operated with fixed pulse duration since the volume of inert gas passing the third pulse valve (265) is largely dictated by the volume or the inert gas storage volume (280) and is less dependent on input pressure or pulse durations. However, gas flow past the third pulse valve (265) may be varied by varying its pulse duration of the third pulse valve (265).

### Pressure Sensors

In further embodiments, the vapor draw system (200) may be configured with one or more gas pressure sensors (285, 290) disposed to meter gas pressure at various locations and to communicate gas pressure signals to the electronic controller (245). Additionally, the controller (245) may be configured with elements for monitoring and recording inert gas pressure signals and for making adjustments to various system operating parameters (e.g. pulse durations), as required to maintain or adjust or maintain inert gas pressure in the inert gas storage volume (280) or the vapor space (220) at desired levels. In one example embodiment, the vapor draw system (200) includes a first gas pressure sensor (285) disposed between the vapor space (220) and the first ALD valve (260) or other suitable locations for monitoring gas pressure in the vapor space (220). In another example embodiment, a second gas pressure sensor (290) is disposed between the gas flow restrictor (265) and the first ALD valve (260) to measure gas pressure inside the inert gas storage volume (280).

In a preferred embodiment, gas storage volume (280) has a gas volume ranging from 0.1-10 ml; however other volumes may be preferred depending on the desired volume and pressure of each inert gas pulse (270).

Additionally, the pulse duration, pulse frequency and phase difference between pulses of each of the third pulse valve (265) and the second ALD valve (260) may be varied according to the volume of the precursor container (210), the level of liquid or solid precursor in the container (210), the volume of the reaction chamber and other parameters of the overall gas deposition system and mode of operation. Generally, each of the ALD pulse valves (250, 260) are capable of operating with pulse durations as short as 5 ms with a preferred pulse duration in the range of 15-100 ms and the third pulse valve (265) may operate with the same operating characteristics as the first and second ALD valve (250, 260) or over a different range of pulse durations e.g. 15 ms to 1 second or more.

The inert gas supply may comprise nitrogen, argon or any other inert gas or mixture of inert gases. In preferred embodiments, each of the ALD pulse valves (250, 260) comprise stainless steel valve fittings such as are available commercially under the name SWAGELOK ALD-3 which are configured for pulse durations as short as 5 milliseconds (ms) and the third pulse valve (265) may comprise the same valve or a pulse valve with different characteristics.

Referring now to FIG. 2a, a vapor draw system (200a) comprises a precursor container (210a) configured with a single input port interfaced with an input conduit (225) and a single output port interfaced with an output conduit (230). In addition, the vapor draw system (200a) includes a first manual valve (235) disposed between the precursor container (210a) and the first ALD pulse valve (260) and a second manual valve (235) disposed between the precursor container (210a) and the second ALD pulse valve (260). Otherwise the vapor draw system (200a) is configured and operates substantially identically with the vapor draw system (200) described above with like elements have matching reference numbers with FIG. 2.

Referring now to FIG. 4 a non-limiting example ALD gas deposition system (400) according to the present invention includes at least two precursor containers (410, 415) with at least one precursor container (410) configured with a vapor draw system (200) as described above. The system (400) includes a gas deposition or reaction chamber (405), a first precursor supply container (410) partially filled with a liquid or solid precursor (412), a vapor draw system (200) associated with the first precursor container (410), and a second precursor supply container (415), which in the present example embodiment does not include a vapor draw system which would be the case if the second precursor container (415) is filled with a gas precursor. However, a second vapor draw system can be associated with the second precursor container (415) if the second precursor requires vaporization.

According to one aspect of the present invention, each of the precursor supply containers (410, 415) is substantially identical and is in fluid communication with a manifold (420) by fluid output conduits (425, 430 respectively). The output conduits (425, 430) extend between a corresponding precursor supply container (410, 415) and the manifold (420) and interface with the manifold at input ports (424, 422). The manifold (420) is in fluid communication with the gas deposition chamber (405) by a manifold conduit (435) which interfaces with the reaction chamber at an input port (444). Alternately, the system (400) can be configured without a manifold (420) and manifold conduit (435) but instead with the output conduits (425, 430) extending from the precursor supply containers directly to the gas deposition chamber (405). Optionally, a manual valve (426) may be disposed between each precursor container and first and second ALD valves (465, 460) to isolate the precursor containers from the reaction chamber. The manual valves (426) are left open when the precursor supply containers are installed in the system (400) and in use, but the manual valves may be closed to remove the precursor supply containers (e.g. for replacement or refilling), or to isolate the precursor supply containers (410, 415) from the reaction chamber (405) and ALD valves (460, 465).

The reaction chamber (405) is in fluid communication with a vacuum pump (440) or other gas evacuation device (e.g. a regenerative blower), which is used to remove gases or outflow from the chamber (405) through a chamber exit port (442) Optionally a precursor trap (445) may be disposed between the vacuum pump (440) and the chamber (405) to remove un-reacted precursor from the outflow exiting through the exit port (442). Optionally a controllable stop valve (450) may be disposed between the chamber (405) and the vacuum pump (440). The stop valve (450) is closed to isolate the chamber from the vacuum pump (440) and opened to allow outflow gases to be removed from the chamber by the pumping action of vacuum pump (440). The stop valve (450) is in communication with an electronic controller (480) which transmits signals to the stop valve to open or close the valve as required. A chamber gas pressure sensor (455) is provided between the chamber (405) and the vacuum pump (440) to sense gas pressure proximate to the exit port (442) and the chamber pressure sensor (455) transmits a pressure signal to the electronic controller (480). Preferably, the chamber pressure sensor (455) is positioned to detect gas pressure within or proximate to the reaction chamber such as between the reaction chamber and the stop valve (450), if a stop valve (450) is included. During ALD cycles, the vacuum pump runs continuously and maintains the reaction chamber at a vacuum pressure (e.g. 0.1-0.5 Torr), unless the stop valve (450) is closed in which case pressure may increase continuously up to 600 Torr.

In operation, one or more substrates (408) to be coated are installed in the chamber (405) through a substrate access port, not shown. The substrates (408) comprise solid materials having external surfaces and the substrates are supported to expose the external surfaces being coated to precursors delivered into the chamber (405). Using an atomic layer deposition (ALD) process or coating recipe, precursors are delivered into the chamber one at a time through the manifold (420) and manifold conduit (435). A first reaction between the first precursor and the exposed surfaces of the substrate (408) alters the exposed surfaces. A second reaction between the second precursor and the altered exposed surfaces further alters the exposed surface and forms a single thin film material layer onto the exposed surfaces. The composition of the thin film layer depends on the composition of the substrate and each of the precursors. The thickness of the thin film generally ranges from 1-10 Å. By repeating the sequence of reactions between the first precursor and the exposed surfaces followed by the reaction of the second precursor and the exposed surfaces, a plurality of thin film layers are built up on the exposed surfaces, one on top of another, a desired material thickness is achieved.

### ALD Process Example

More specifically, an example ALD process performed by the system (400) comprises introducing an inert gas pulse into the first precursor container (410) using any one of the vapor draw system embodiments described above, and thereafter exclusively introduces a first precursor pulse from the precursor container (410) into the reaction chamber (405). The first precursor pulse is introduced by pulsing the ALD valve (460) with the ALD boost valve (498) closed. The first precursor pulse reacts with the exposed surfaces for an exposure time t1, which is substantially the time duration that the first precursor pulse remains in the reaction chamber. The reaction between the first precursor and the exposed surfaces is self-limiting in that once all of the available bonding sites on the exposed surfaces react with the first precursor, no further reaction is possible. The reaction between the first precursor and the exposed surfaces alters the exposed surfaces both physically and chemically. Once the reaction between the first precursor and the exposed surfaces is completed or at the end of a predetermined exposure time, the first precursor is purged or flushed from the reaction chamber (e.g. by flushing the reaction chamber (405) with inert gas through the manifold (420), while removing gases from the reaction chamber (405) with the vacuum pump (440)). In preferred embodiments, the vacuum pump (440) operates continuously, removing gas from the reaction chamber during both precursor input and inert gas flush phases of the ALD cycle, unless the stop valve (450) is closed. If a trap (445) is provided, an exposed surface of a solid substrate contained within the trap reacts with unreacted portions of the first precursor pulse to remove the unreacted portions of the first precursor from the gas outflow.

The example ALD process performed by the system (400) further comprises exclusively introducing a second precursor pulse from the second precursor container (415) into the reaction chamber. The second precursor pulse is introduced by pulsing the ALD valve (465). The second precursor pulse reacts with the exposed surfaces, after they have been altered by the reaction with the first precursor, for an exposure time t2, which is substantially the time duration that the second precursor pulse remains in the reaction chamber (405). The reaction between the second precursor and the exposed surfaces is also self-limiting in that once all of the available bonding sites on the exposed surfaces react with the second precursor, no further reaction is possible. The reaction of the second precursor with the altered exposed surfaces forms a thin film material layer onto the exposed surfaces. The second reaction also renders the exposed surfaces suitable for repeating the first reaction with the first precursor. Once the second reaction is completed or at the end of a predetermined exposure time, the second precursor is purged or flushed from the reaction chamber (e.g. by flushing the reaction chamber (405) with inert gas through the manifold (420), while removing gases from the reaction chamber (405) with the vacuum pump (440). In preferred embodiments, the vacuum pump (440) operates continuously, removing gas from the reaction chamber during both precursor input and inert gas flush phases of the ALD cycle, unless the stop valve (450) is closed. If a trap (445) is provided, an exposed surface of a solid substrate contained within the trap reacts with unreacted portions of the second precursor pulse to remove the unreacted portions of the second precursor from the gas outflow.

The system (400) includes a first precursor pulse or ALD valve (460) disposed between each precursor supply container (410) and the manifold (420) or reaction chamber (405) if no manifold is used. The first precursor ALD pulse valve (460) is pulsed in order to release a first precursor pulse from the first precursor container (410) to the reaction chamber (405) through the conduits (425, 435) respectively, or the conduit (425) may be connected directly to the chamber (405). The second ALD pulse valve (465) is pulsed in order to release a second precursor pulse from the precursor container (415) to the reaction chamber (405) through the conduits (430, 435) respectively, or the conduit (430) may be connected directly to the chamber (405). The vacuum pump (440) operates continuously and the reaction chamber (405) is maintained at a vacuum pressure and precursor pulses are drawn into and out of the reaction chamber by the pumping action of the vacuum pump unless the stop valve (450) is closed to increase exposure time.

In one embodiment, an inert gas supply (478) is continuously delivered into the manifold (420) during each of the precursor pulse cycles and each of the flush cycles. During precursor pulse cycles the inert gas delivered into the manifold by the inert gas supply (478) mixes with precursor pulses and carries the precursor pulses into and through the reaction chamber. During chamber flush cycles inert gas is exclusively delivered into the manifold by the inert gas supply (478) and is drawn into and through the reaction chamber by the pumping action of the vacuum pump (440). The stop valve (450), if included, is open during flush cycles.

In an alternate non-limiting example embodiment, each of the first and second precursor ALD pulse valves (460) and (465) includes a second input port connected to an inert gas supply (470) and (475) respectively. The pulse valves (460) and (465) include two separate input ports and one output port and each ALD pulse valve (460, 465) includes two pulse actuators independently controlled by the controller (480). At each ALD valve, one pulse actuator is configured to deliver precursor pulses to the reaction chamber and a second pulse actuator is configured to modulate inert gas flow through the ALD valve. Alternately the ALD pulse valves (460, 465) each have a single actuator for delivering precursor pulses but no actuator for modulating inert gas and in this configuration inert gas flows continuously from the inert gas supplies (457) and (490) through the ALD valve to the manifold. In both cases inert gas is mixed with precursor pulses inside the ALD valve or within the conduit (430) between the pulse vales and the manifold (420) and each precursor pulse is carried to the reaction chamber by the inert gas flow entering the ALD valve from the inert gas supplies (470, 475). Accordingly, in one operating mode the flow of inert gas into the chamber (405) is modulated by the ALD valves (460,465), (e.g. to stop or reduce the flow of inert gas during precursor pulse cycles and start or increase the flow of inert gas during purge cycles). In another operating mode inert gas enters each of the ALD pulse valves (460, 465) and continuously flows to the chamber (405). In this case the inert gas mixes with and carries precursor pulses to the reaction chamber (405) during precursor pulse cycles and inert gas flows exclusively through the chamber during purge cycles. In either case, inert gas may flow into and the ALD pulse valves (460, 465) and into the chamber (405) through the manifold (420) to either flush the manifold and chamber of precursor gas or carry precursor pulses through the manifold (420) and the chamber (405). Generally, each thin film growth cycle carried out by the ALD system (400) is controlled by the electronic controller (480), which controls the introduction of precursors into the chamber (405) by opening and closing appropriate precursor ALD pulse valves (460,465) in an appropriate sequence and at a desired pulse frequency. If each of the ALD pulse valves (460,465) includes two actuators and inert gas (470, 475) supplies input to the ALD pulse valves, the electronic controller modulates inert gas flow to the chamber (405) by modulating the second ALD pulse valve actuators. In addition, the electronic controller (480) controls the operation of the vapor draw system (200), as well as precursor heaters (485) and other heaters, not shown, for heating the reaction chamber (405) and or substrates (408), the trap (445) and other elements of the system (400) as required. Additionally the electronic controller (480) is interfaced with various sensors such a pressure (455) and temperature sensors (not shown), to sense system conditions. Moreover, the electronic controller (480) is programed with feedback loops, operating programs for managing ALD cycles, a user interface and other hardware and software components configured to manage system operation in various operating modes and states.

The system (400) may also include additional precursor containers interfaced with the manifold (420) with the additional precursors containers each being interfaced to the manifold (420) via an electronically controlled precursor ALD pulse valve substantially as shown in FIG. 4 to allow a user to select between various precursor combinations as may be required to deposit thin films having different material compositions onto exposed surfaces of different substrates. One or a plurality of the precursor containers may include the vapor draw system (200) described above.

### First Example Operating Sequence

In the above described ALD system (400), a first example operating sequence according to the present invention includes the following steps. An inert gas pulse or boost pulse is injected into the first precursor container (410) by pulsing the ALD valve (498). A first precursor pulse is released from the precursor container (410) to the reaction chamber by pulsing the ALD valve (460). The first precursor is purged from the reaction chamber (405). A second precursor pulse is released from the second precursor container (415) to the reaction chamber (405) by pulsing the ALD valve (465). The second precursor is purged from the reaction chamber (405).

The first example operating sequence deposits a single thin film material layer onto exposed surfaces of the substrate (408). Typically the first example operating sequence is repeated a plurality of times to increase film thickness on the exposed surfaces to a desired level. Optionally the first example operating sequence may include the additional steps removing unreacted first and second precursor from the reaction chamber (405) outflow during each of the purging steps.

### Second Example Operating Sequence

In the above described ALD system (400), a second example operating sequence according to the present invention includes the following steps. An inert gas or boost pulse is injected into the first precursor container (410) by pulsing the ALD boost valve (498). A first precursor pulse is released from the precursor container (410) to the reaction chamber (405) by pulsing the ALD valve (460). An inert gas pulse is injected into the first precursor container (410) by pulsing the ALD valve (498). A first precursor pulse is released from the precursor container (410) to the reaction chamber (405) by pulsing the ALD valve (460). The first precursor is purged from the reaction chamber (405). A second precursor pulse is released from the second precursor container (415) to the reaction chamber (405) by pulsing the ALD valve (465). The second precursor pulse is purged from the reaction chamber (405).

The second example operating sequence deposits a single thin film material layer onto exposed surfaces of the substrate (408). Two or more first precursor pulses are delivered into the reaction chamber (405) to react with the exposed surface before the exposed surfaces are allowed to react with the second precursor. Each of the two or more precursor pulses is preceded by injecting an inert gas boost pulse into the first precursor container. The reaction chamber (405) is only purged of the first precursor after all of the two or more first precursor pulses have been delivered into the reaction chamber. Typically the second example operating sequence is repeated a plurality of times to increase film thickness on the exposed surfaces to a desired level. Optionally, the second example operating sequence may include the additional steps removing unreacted first and second precursor from the reaction chamber (405) outflow during each of the purging steps.

### Third Example Operating Sequence

In the above described ALD system (400), a third example operating sequence according to the present invention includes the following steps. An inert gas boost pulse is injected into the first precursor container (410) by pulsing the ALD valve (498). The stop valve (450) is closed. A first precursor pulse is released from the precursor container (410) to the reaction chamber (405) by pulsing the ALD valve (460). Optionally, an inert gas pulse is injected into the first precursor container (410) by pulsing the ALD valve (498) and another first precursor pulse from the precursor container (410) is released to the reaction chamber by pulsing the ALD valve (460). The stop valve (450) is opened. The first precursor is purged from the reaction chamber (405). A second precursor pulse is released from the second precursor container (415) to the reaction chamber (405) by pulsing the ALD valve (465). The second precursor pulse is purged from the reaction chamber.

The third example operating sequence deposits a single thin film material layer onto exposed surfaces of the substrate (408). Two or more first precursor pulses are optionally delivered into the reaction chamber (405) to react with the exposed surface before the stop valve (450) is opened and before the exposed surfaces are allowed to react with the second precursor. Each of the two or more first precursor pulses is preceded by injecting an inert gas boost pulse into the first precursor container. The reaction chamber is only purged of the first precursor after the two or more first precursor pulses have been delivered into the reaction chamber. Typically the third example operating sequence is repeated a plurality of times to increase film thickness on the exposed surfaces to a desired level. Optionally the third example operating sequence may include the additional steps removing unreacted first and second precursor from the reaction chamber (405) outflow during each of the purging steps.

### Fourth Example Operating Sequence

In the above described ALD system (400), a fourth example operating sequence according to the present invention includes the following steps. An inert gas pulse is injected into the first precursor container (410) by pulsing the ALD valve (498). A first precursor pulse is released from the precursor container (410) to the reaction chamber by pulsing the ALD valve (460). The first precursor is purged from the reaction chamber. An inert gas pulse is injected into the first precursor container (410) by pulsing the ALD valve (498). Another first precursor pulse from the precursor container (410) is released to the reaction chamber by pulsing the ALD valve (460). The first precursor is purged from the reaction chamber. A second precursor pulse is released from the second precursor container (415) to the reaction chamber by pulsing the ALD valve (465). The second precursor is purged from the reaction chamber (405) by exclusively flowing inert gas through the reaction chamber (405).

The fourth example operating sequence deposits a single thin film material layer onto exposed surfaces of the substrate (408). The fourth example operating sequence may also include releasing more than two first precursor pulses into the reaction chamber (405) to react with the exposed surface before the exposed surfaces are allowed to react with the second precursor. Each first precursor pulse is preceded by injecting an inert gas boost pulse into the first precursor container (410). The reaction chamber is purged after each first precursor pulse is delivered into the reaction chamber (405). Typically the fourth example operating sequence is repeated a plurality of times to increase film thickness on the exposed surfaces to a desired level. Optionally the fourth example operating sequence may include the additional steps of removing unreacted first and second precursor from the reaction chamber (405) outflow during each of the purging steps.

The first, second, third and fourth example operating sequences may be performed using a vapor draw system (200) associated with each of the first (410) and second (415) precursor containers. In that case, the operating sequence associated with injecting an inert gas boost pulse into the first precursor container (410) is repeated for the second precursor container (4150 and the step of releasing a plurality of first precursor pulses into the reaction chamber (405) before releasing the second precursor into the reaction chamber can be repeated for the second precursor such that both precursor release steps comprise releasing a plurality of same precursor pulses to the reaction chamber before releasing a different precursor pulse to the reaction chamber.

The first, second, third and fourth example operating sequences may be performed with a continuous flow of inert gas passing through the reaction chamber (405) (e.g. from any one of or a plurality of the inert gas supplies (470, 475, 478) during the entire operating sequence). In this embodiment, the purge steps are substantially continuous since inert gas is substantially constantly purging the reaction chamber and precursor pulses are carried through the reaction chamber and purged therefrom by the constant flow of inert gas.

As compared to conventional gas bubblers and ALD systems operating with conventional gas bubblers, the vapor draw systems (200, 200a), the ALD system (400), and the operating sequence examples described above offer a more refined degree of control over the volume of each precursor pulse and the reaction chamber boost or peak pressure associated with a precursor pulse. Additionally, the vapor draw systems (200, 200a), the ALD system (400) and the operating sequence examples described above offer a more refined degree of control over the volume or each inert gas or boost pulse and the total gas pressure inside the precursor container (210, 410). As compared to conventional gas bubblers, the ALD pulse valves (260, 498) and gas flow restrictors (265, 495) of the present invention provide a more refined degree of control over tuning precursor vaporization as required to achieve a saturated reaction rate. As compared to conventional gas bubblers and ALD systems operating with conventional gas bubblers, the vapor draw systems (200, 200a) and operating methods of the present invention consume considerably less precursor even when a plurality of same precursor pulses are released to the reaction chamber for each ALD cycle. As compared to conventional ALD systems, the ALD system (400) and the above described operating sequence examples offer a means for empirically determining when a saturated growth rate is achieved in a given ALD cycle by allowing a user to deliver a plurality of same precursor pulses to the reaction chamber (405) and determine how many same precursor pulse deliveries are required to achieve a saturated growth rate. Additionally, the vapor draw system (200), ALD system (400), and example operating sequences described above are usable with conventional gas precursor containers or more generally with single port precursor containers (210) since the vapor draw system (200) interfaces with and injects inert gas pulses into a vapor space (220) and releases precursor pulses from the vapor space through the same port. Additionally, as compared with conventional gas bubblers, the inert gas containers (210, 210a) of the present invention do not require an inert gas input conduit to extend below the level of the solid or liquid precursor in the precursor container, and this overcomes the problem of conventional gas bubblers that precursor pulse volume and vapor pressure varies as the level of liquid or solid precursor in the container decreases. Additionally, by not requiring the inert gas input conduit to extend below the level of solid or liquid precursor in the precursor container the precursor containers (210) and (210a) are less complex and able to be manufactured at reduced cost. Additionally, the ALD system (400) can be configured to operate with substantially identical and interchangeable single port precursor containers for gas, liquid and solid precursors and this also reduces ALD system cost and complexity.

As described above, the vapor draw system (200) and ALD system (400) enable low vapor pressure liquid and solid precursors to be vaporized and the ALD system to operate at a saturated growth rate with precursor temperature maintained below a thermal breakdown temperature of the precursor. This mode of operation is made possible by two aspects of the present invention, namely injecting a controlled volume inert gas boost pulse into the vapor space (220) prior to releasing each precursor pulse from the vapor space and by delivering a plurality of same precursor pulses into the reaction chamber during each ALD cycle, wherein the number of same precursor pulses is selected to correspond with a saturated growth rate. Additionally, both of these aspects of the present invention have benefit whether used separately or jointly and both can be varied independently to achieve a saturated growth rate for various precursors and ALD cycles. In practical experimental examples shown below, further benefits of the present invention are made clear including the unexpected benefit that the use of a plurality of same precursor pulses each including a prior inert gas boost pulse enable the ALD system (400) to be operated at reduced precursor temperatures with improving thin film coating uniformity.

### EXAMPLE 1

Example 1 relates to operating the ALD system (400) according to the first and second operating sequences described above and comparing film growth performance to a conventional ALD operating sequence which does not include injecting an inert gas boost pulse into the precursor container and does not include releasing a plurality of same first precursor pulses into the reaction chamber before releasing a different second precursor pulse into the reaction chamber.

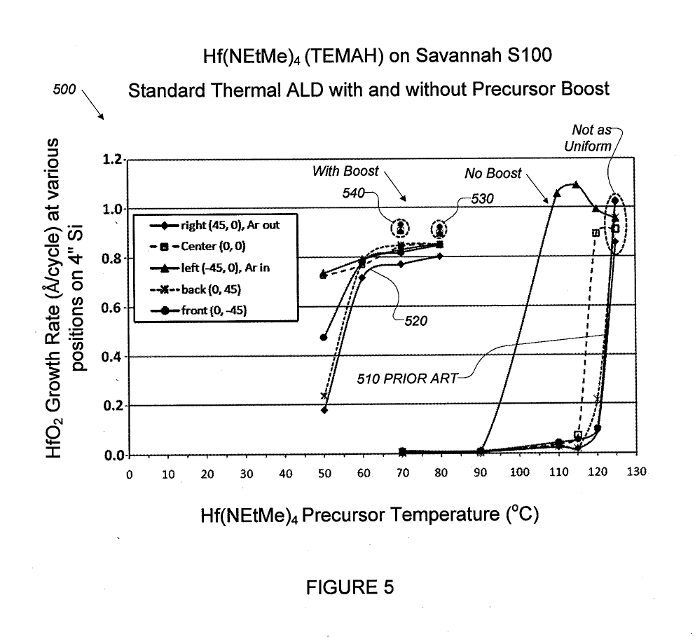

FIG. 5 depicts a plot (500) including curve sets (510) and (520) and data points (530) and (540). The (510) curves show film growth characteristics of a conventional ALD system and operating sequence performed without an inert gas boost pulse. The (520) curves show film growth characteristics of the ALD system (400) using the first operating sequence described above according to the present invention. The data point (530) shows film growth characteristics of the ALD system (400) using the second operating sequence described above wherein two boosted first precursors are delivered into the reaction chamber per ALD cycle according to the present invention. The data point (540) shows film growth characteristics of the ALD system (400) using the second operating sequence described above wherein three boosted first precursor are delivered into the reaction chamber per ALD cycle according to the present invention.

The ALD cycle being performed is growing or depositing a hafnium oxide (HfO₂) film onto a silicon wafer substrate. The first precursor comprises tetrakis (ethylmethylamino) hafnium (Hf(NEtMe)₄) which is a low vapor pressure liquid precursor contained within the first precursor container (410). The second precursor is water (H₂O) contained within the second precursor container (415). The second precursor (H₂O) has a vaporization temperature of 100° C. and provides sufficient vapor pressure at 100° C. to be vaporized without a vapor draw system.

The curves (510, 520) and data points (530, 540) plot (HfO₂) film growth at a plurality of locations on a circular silicon wafer substrate. The film growth in Å per ALD cycle is displayed on the vertical axis and the temperature of the first precursor (Hf(NEtMe)₄) is displayed on the horizontal axis. Each ALD growth cycle was performed at a plurality of first precursor temperatures ranging approximately from 50 to 125° C. Each curve set (510, 520) includes five curves corresponding to five positions on the circular substrate. The left position is proximate to an inert gas input port that delivers inert gas into the reaction chamber and the right position is proximate to an inert gas output port that removes inert gas from the reaction chamber. A saturated growth rate is achieved when film growth in Å per ALD cycle is substantially equal at all five positions on the circular substrate. In the present example the circular substrate comprises a 100 mm (4 inch) diameter circular silicon wafer.

Referring now to the curves (510) associated with conventional film growth without an inert gas boost pulse, an acceptable saturated growth rate is approximately achieved at a first precursor temperature of 125° C. and the saturated growth rate produces a (HfO₂) film thickness of approximately 0.9 Å per ALD cycle. It is also noted that film growth rate at the substrate left position proximate to the reaction chamber inert gas input port behaves differently than film growth rate at other positions on the substrate and this may be due to the inert gas input port causing non-uniform precursor vapor distribution in the reaction chamber.

Referring now to the curves (520) associated with film growth characteristics of the ALD system (400) using the first operating sequence described above, an acceptable saturated growth rate is approximately over a first precursor temperature of 65° to 80° C. and the saturated growth rate produces a (HfO₂) film thickness approximately ranging from 0.75 to 0.85 Å per ALD cycle. It is also noted that the curves (520) show a more uniform (HfO₂) film thickness over the five substrate positions and this leads to a thin film layer that has more uniform physical and chemical characteristics which is highly desirable.

Referring now to the isolated data points (530, 540) which are associated with film growth characteristics of the ALD system (400) using the second operating sequence described above. The data point (530) represents film growth using two first precursor pulses per second precursor pulse and the data point (540) pulse represents film growth using three first precursor pulses per second precursor pulse with each first precursor pulse being preceded by an inert gas boost pulse. In the case of the data point (530), which corresponds to a first precursor temperature of 80° C., and two first precursor pulses per ALD cycle, the (HfO₂) film thickness per ALD cycle is slightly increased to 0.85 Å per ALD cycle. In the case of the data point (540), which corresponds to a first precursor temperature of 70° C., and three first precursor pulses per ALD cycle, the (HfO₂) film thickness per ALD cycle is slightly increased to 0.9 Å per ALD cycle at a lower precursor temperature.

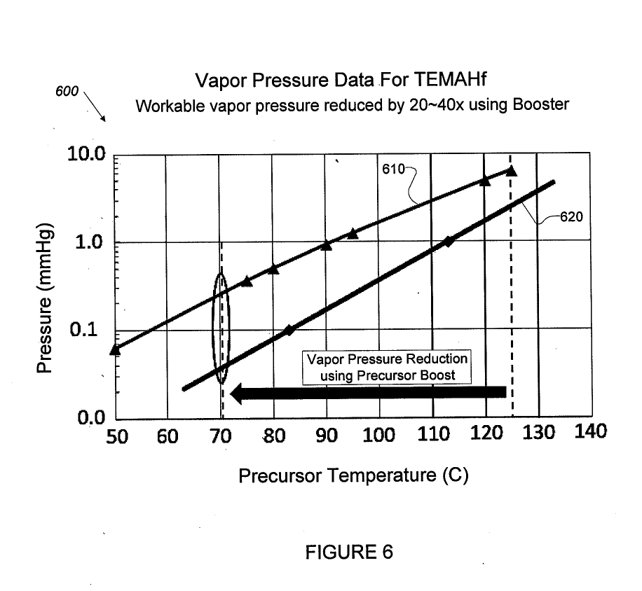

FIG. 6 depicts a plot (600) showing data curves for vapor pressure in mmHg vs. first precursor temperature (Hf(NEtMe)₄) in ° C. The first curve (610) is based on Sigma Aldrich Fine Chemicals (SAFC) data and the second curve (610) is based on Hausmann experimental data. Both curves show a (Hf(NEtMe)₄) vapor pressure between 1 and 10 mmHg at a temperature of 125° C. and (Hf(NEtMe)₄) vapor pressure between 0.02 and 0.3 mmHg at 70° C. When compared to curves (510) and (520) of plot (500) which shows that acceptable growth rates are achievable at a (Hf(NEtMe)₄) temperature of 70° C. when an inert gas boost pulse is injected into the precursor container according to the present invention, it appears that each boost pulse reduces the workable vapor pressure of (Hf(NEtMe)₄) by a factor or 20-40x or of reducing the required vapor pressure from approximately 3 mmHg or 3 torr to approximately 0.1 mmHg or 0.1 torr. Moreover the data points (530) and (540) show that using two (Hf(NEtMe)₄) precursor pulses per ALD cycle increases (HfO₂) film thickness per ALD cycle at and using three (Hf(NEtMe)₄) precursor pulses per ALD cycle increases (HfO₂) film thickness per ALD cycle and further reduces the workable vapor pressure.

More generally, the present invention is suitable for ALD coating cycles where it is desirable to use low vapor pressure precursors such as organometallics. The present invention is suitable for precursors that have practical vaporization temperatures with vapor pressures in the range to 0.05 to 1 torr. In many cases, use of the present invention can reduce the usable precursor's temperature to below a thermal breakdown temperature of the precursor, thereby enabling ALD coating with precursors that were previously unusable. Some solid precursor examples include NiCp₂, MgCp₂, and Hf(NEtMe)₄. Some liquid precursor examples include Er(iPrCp)₃, Ni(iPrCp)₂, and Ni(EtCp)₂.

What is claimed is:

1. A gas deposition system comprising:
a first precursor container partially filled with a non-vaporized precursor and including a vapor space;
an inlet conduit extending between an inert gas supply and the vapor space;
an outlet conduit extending between the vapor space and a reaction chamber;
a first pulse valve disposed along the outlet conduit between the vapor space and a reaction chamber;
a second pulse valve disposed along the inlet conduit between the inert gas supply and the vapor space;
a gas flow restrictor disposed along the inlet conduit between the inert gas supply and the second pulse valve.

2. The gas deposition system of claim 1 further comprising a controller in communication with each of the first and second pulse valves for independently pulsing each of the first and second pulse valves.

3. The gas deposition system of claim 1 wherein the first precursor container includes an outer wall having a single port passing there though to the vapor space and wherein each of the inlet and outlet conduits is in fluid communication with the vapor space through the single port.

4. The gas deposition system of claim 1 further comprising a gas pressure sensor in communication with the controller and positioned to monitor gas pressure in the vapor space.

5. The gas deposition system of claim 2 further comprising a heater disposed to heat the non-vaporized precursor inside the first precursor container and a temperature sensor in communication with the controller and positioned to monitor a temperature of the non-vaporized precursor.

6. The gas deposition system of claim 1 wherein the gas flow restrictor comprises an orifice.

7. The gas deposition system of claim 6 wherein the inert gas supply has an inlet pressure ranging from 20-40 psi and the orifice has a circular diameter in the range of 100-150 microns.

8. The gas deposition system of claim 2 wherein the gas flow restrictor comprises:
a third pulse valve disposed along the inlet conduit between the inert gas supply and the second pulse valve;
an inert gas storage volume disposed between the second and third pulse valves; and,
wherein the controller is in communication with the third pulse valve for independently pulsing the third pulse valve.

9. The gas deposition system of claim 8 further comprising a gas pressure sensor in communication with the controller and positioned to monitor gas pressure in the inert gas storage volume.

10. The gas deposition system of claim 8 wherein the inert gas storage volume comprises a variable volume.

11. The gas deposition system of claim 2 wherein each of the first and second pulse valves is operable with pulse durations in the range of 5 msec to 1 second.

12. The gas deposition system of claim 8 wherein each of the first, second, and third pulse valves is operable with pulse durations in the range of 5 msec to 1 second.

13. The gas deposition system of claim 11 wherein the controller is configured to independently operate each of the first and second pulse valves at any pulse duration in the pulse duration range.

14. The gas deposition system of claim 12 wherein the controller is configured to independently operate each of the first, second, and third pulse valves at any pulse duration in the pulse duration range.

15. The gas deposition system of claim 2 wherein the controller is configured to independently vary the pulse frequency of each of the first and second pulse valves.

16. The gas deposition system of claim 8 wherein the controller is configured to independently vary the pulse frequency of each of the first, second, and third pulse valves.

17. The gas deposition system of claim 2 wherein each pulse of the first pulse valve injects an inert gas pulse into the vapor space and the volume of the inert gas pulse ranges from 0.1 to 4.0 ml.

18. The gas deposition system of claim 2 wherein each pulse of the first pulse valve injects an inert gas pulse into the vapor space and the volume or the inert gas pulse ranges from 0.4% to 16% of a volume or the vapor space.

19. The gas deposition system of claim 2 wherein each pulse of the first pulse valve injects an inert gas pulse into the vapor space and the volume or the inert gas pulse ranges from 0.1% to 200% of a volume or the vapor space.

20. A gas deposition method comprising:
partially filling a first precursor container with a non-vaporized precursor and providing a vapor space in the first precursor container;
closing a first pulse valve disposed along an outlet conduit between the vapor space and a reaction chamber;
injecting an inert gas pulse into the vapor space with the first pulse valve closed;
closing a second pulse valve disposed along the inlet conduit between the inert gas supply and the vapor space;
releasing a precursor pulse from the vapor space to the reaction chamber with the second pulse valve closed.

21. The gas deposition method of claim 20 further comprising restricting gas flow between the inert gas supply and the second pulse valve with an orifice.

22. The gas deposition method of claim 21 further comprising heating the non-vaporized precursor to a temperature that is below a thermal breakdown temperature of the non-vaporized precursor.

23. The gas deposition method of claim 22 further comprising repeating steps of;
closing the first pulse valve;
injecting an inert gas pulse into the vapor space with the first pulse valve closed;
closing the second pulse valve;
releasing a precursor pulse from the vapor space to the reaction chamber with the second pulse valve closed.

24. A gas deposition method comprising:
partially filling a first precursor container with a non-vaporized precursor and providing a vapor space in the first precursor container;
closing a first pulse valve disposed along an outlet conduit between the vapor space and a reaction chamber;
closing a second pulse valve disposed along the inlet conduit between the inert gas supply and the vapor space;
closing a third pulse valve disposed along the inlet conduit between the inert gas supply and the second pulse valve;
pulsing the third pulse valve to fill an inert gas storage volume disposed between the second pulse valve and a third pulse valve with a volume of inert gas;
pulsing the second pulse valve to transfer the volume of inert gas stored in the inert gas storage volume into the vapor space;
pulsing the first pulse valve to release a precursor pulse from the vapor space to the reaction chamber.

25. The gas deposition method of claim 24 further comprising heating the non-vaporized precursor to a temperature that is below a thermal breakdown temperature of the non-vaporized precursor. A gas deposition method comprising:
a) partially filling a first precursor container with a first non-vaporized precursor and providing a vapor space in the first precursor container;
b) closing a first pulse valve disposed along an outlet conduit between the vapor space and a reaction chamber;
c) injecting an inert gas pulse into the vapor space with the first pulse valve closed;
d) closing a second pulse valve disposed along the inlet conduit between the inert gas supply and the vapor space;
e) releasing a precursor pulse comprising the first precursor from the vapor space to the reaction chamber with the second pulse valve closed;
f) reacting the first precursor with a substrate disposed inside the reaction chamber;
g) repeating steps c-f;
h) purging the reaction chamber of the first precursor;
i) releasing a precursor pulse comprising a second precursor into the reaction chamber and reacting the second precursor with the substrate;
j) purging the reaction chamber of the second precursor.

26. The gas deposition method of claim 25 wherein each cycle of the steps b-j comprises depositing a single material layer onto exposed surfaces of the substrate; further comprising repeating steps b-j until a desired number of material layers are deposited onto the exposed surfaces.

27. The gas deposition method of claim 26 further comprising heating the non-vaporized precursor to a temperature that is below a thermal breakdown temperature of the non-vaporized precursor.

28. The gas deposition method of claim 27 wherein the first precursor container comprises a single port container and steps c and e comprise passing the inert gas pulse and the precursor through the single port.
